(19) United States
(12) Patent Application Publication
(10) Pub. No.: US 2005/0263754 A1
(43) Pub. Date: Dec. 1, 2005

(54) Substrates for growth of chemical compound semiconductors, chemical compound semiconductors using the substrates and processes for producing thereof

(75) Inventors: Jun Komiyama, Hadano-shi (JP); Yoshihisa Abe, Sagamihara-shi (JP); Shuniti Suzuki, Hadano-shi (JP); Hideo Nakanishi, Hadano-shi (JP); Toru Kita, Matsudo-shi (JP)

Correspondence Address: FOLEY AND LARDNER;SUITE 500, 3000 K STREET NW, WASHINGTON, DC, 20007, US

(73) Assignee: TOSHIBA CERAMICS CO., LTD.

(21) Appl. No.: 10/953,867

(22) Filed: Sep. 30, 2004

(30) Foreign Application Priority Data
May 25, 2004 (JP) 2004-155050
Jun. 23, 2004 (JP) 2004-184974

(51) Int. Cl. H01L 29/08; H01L 23/58

(52) U.S. Cl. 257/40; 257/744; 257/750; 257/631

(57) ABSTRACT

In a substrate for growth of a chemical compound semiconductor, at least on one surface of a Si single crystal substrate 2 with a thickness of 300 μm, a porous Si single crystal 4 is formed. Pores of the porous Si single crystal 4 is opened outward. The surface of the porous Si single crystal 4 is covered by a 3C—SiC single crystal layer 3 with a thickness of 1 nm. The thickness of the porous Si single crystal 4 is, for example, 10 μm.

### CROSS-REFERENCE TO RELATED APPLICATIONS

This application is based upon and claims the benefit of priority from the prior Japanese Patent Applications No. 2004-155050, filed on 25th May, 2004 and No. 2004-184974, filed on 23rd Jun., 2004, the entire contents of which are incorporated herein by reference.

### BACKGROUND OF THE INVENTION

(1) Field of the Invention

The present invention relates to a substrate for growth of a chemical compound semiconductor i.e. compound semiconductor used to allow a single crystal film for producing, for example, a short-wave semiconductor luminous element or a highly efficient high-frequency semiconductor element to grow in a vapor phase, a chemical compound semiconductor (a compound semiconductor) using it, and a process for producing them.

(2) Description of the Related Art

Conventionally, as such a substrate for growth of a chemical compound semiconductor and a process for producing it, a process for producing a semiconductor base by heat-treating a Si single crystal substrate having a porous Si single crystal layer at a temperature lower than the melting point of the porous Si single crystal layer in a non-oxidizable atmosphere or a vacuum, thereby forming a non-porous Si single crystal layer and a semiconductor base produced by the process are known (refer to Japanese Patent 2901031).

A porous Si single crystal is known to include, just like sponge, many fine holes (having a diameter of several nm) opened outward in the Si single crystal.

A porous Si single crystal layer is known to be able to form on a Si single crystal substrate at a depth of several nm to several μm from the surface thereof or overall in the thickness direction of the Si single crystal substrate. Even if a porous Si single crystal layer is formed overall in the thickness direction, the porous Si single crystal layer can be used independently as a substrate. Such a substrate is called a porous Si single crystal substrate.

When a substrate for growth of a chemical compound semiconductor is composed of the same kind of Si single crystal film as that of a Si single crystal substrate, there are no faults caused to a semiconductor laminated by vapor phase growth.

However, when the substrate for growth of a chemical compound semiconductor is composed of a different kind of chemical compound semiconductor single crystal film from that of the Si single crystal substrate, crystal defects such as a transformation which can be considered to be caused by stress due to lattice mismatching or a difference in the thermal expansion coefficient occur in high density and there are faults which cannot withstand actual use.

### BRIEF SUMMARY OF THE INVENTION

According to embodiments of the present invention, an object of the present invention is to provide a substrate for growth of a chemical compound semiconductor capable of improving the quality of a chemical compound semiconductor, a chemical compound semiconductor using it, and a process for producing them.

The present invention may provide a substrate for growth of a chemical compound semiconductor, comprising:
(1) a Si single crystal substrate and
(2) a porous Si single crystal layer formed on at least one surface of the Si single crystal substrate.

The present invention may provide a chemical compound semiconductor comprising a chemical compound semiconductor layer (film) installed on the substrate for growth of a chemical compound semiconductor.

The present invention may provide a process for producing a substrate for growth of a chemical compound semiconductor and a chemical compound semiconductor, comprising the steps of:
(1) forming a porous Si single crystal layer by making at least one surface of a Si single crystal substrate porous,
(2) heat-treating the porous Si single crystal layer at 800 to 1400° C. in an atmosphere which include carbon and carbonizing a part or the whole thereof, and
(3) further forming a chemical compound semiconductor layer (film) when producing a chemical compound semiconductor.
   Incidentally, in the present invention, chemical bonding of carbon is referred as to carbonization.

### BRIEF DESCRIPTION OF THE DRAWINGS

Further objects and advantages of the invention can be more fully understood from the following detailed description taken in conjunction with the accompanying drawings, in which:

FIG. 1 is a conceptual cross sectional view of a substrate for growth of a chemical compound semiconductor relating to an embodiment of the present invention,

FIG. 2 is an illustration showing a process for producing the substrate for growth of a chemical compound semiconductor shown in FIG. 1,

FIG. 3 is a conceptual cross sectional view of a substrate for growth of a chemical compound semiconductor relating to another embodiment of the present invention,

FIG. 4 is an illustration showing a process for producing the substrate for growth of a chemical compound semiconductor shown in FIG. 3,

FIG. 5 is a conceptual cross sectional view of a substrate for growth of a chemical compound semiconductor relating to still another embodiment of the present invention,

FIG. 6 is drawings showing a process for producing the substrate for growth of a chemical compound semiconductor shown in FIG. 5, and FIG. 6A is an illustration for the first step, and FIG. 6B is an illustration from the final step.

FIG. 7 is a conceptual cross sectional view of a substrate for growth of a chemical compound semiconductor relating to a further embodiment of the present invention,

FIG. 8 is a conceptual cross sectional view of a substrate for growth of a chemical compound semiconductor relating to a still further embodiment of the present invention,

FIG. 9 is drawings showing a process for producing the substrate for growth of a chemical compound semiconductor shown in FIG. 8, and FIG. 9A is an illustration for the first step, and FIG. 9B is an illustration from the second step, and FIG. 9C is an illustration for the third step, and FIG. 9D is an illustration from the fourth step, and FIG. 9E is an illustration for the final step,

FIG. 10 is an illustration for XRD evaluation of a 3C—SiC single crystal film of a substrate for growth of a chemical compound semiconductor for comparison with the substrate for growth of a chemical compound semiconductor shown in FIG. 8, and

FIG. 11 is a conceptual cross sectional view of a chemical compound semiconductor relating to an embodiment of the present invention.

### DETAILED DESCRIPTION OF THE INVENTION

An embodiment of the present invention will be explained below.

On at least one surface of a Si single crystal substrate, a porous Si single crystal layer or a porous 3C—SiC single crystal layer is formed and on the porous Si single crystal layer or the porous 3C—SiC single crystal layer, a SiC single crystal layer may be formed. A Si single crystal layer may be formed instead of the SiC single crystal layer. On the SiC single crystal layer, the porous Si single crystal layer, the porous 3C—SiC single crystal layer or the Si single crystal layer, a 3C—SiC single crystal layer (film) (cubic silicon carbide single crystal) may be further formed. The Si single crystal substrate may be removed by scission or separation of the porous Si single crystal layer. The porous Si single crystal layer may be a recrystallized Si single crystal layer. A c-BP (cubic boron phosphate) single crystal layer may be formed under the 3C—SiC single crystal layer (film) or a chemical compound semiconductor single crystal film.

The process for producing a substrate for growth of a chemical compound semiconductor forms a porous Si single crystal layer on a Si single crystal substrate, then heat-treats the porous Si single crystal layer in an atmosphere which include carbon and carbonizes the surface layer part up to a desired depth from the surface thereof.

The process for producing a substrate for growth of a chemical compound semiconductor forms a porous Si single crystal layer on a Si single crystal substrate, laminates a Si single crystal layer by vapor phase growth (vapor deposition), heat-treats the porous Si single crystal layer in an atmosphere which include carbon, and carbonizes the upper part thereof. Thereafter, the Si single crystal substrate may be removed by scission or separation of the porous Si single crystal layer.

The process for producing a substrate for growth of a chemical compound semiconductor or a chemical compound semiconductor forms a porous Si single crystal layer on a Si single crystal substrate, then anneals the porous Si single crystal layer, recrystallizes it up to a desired depth, and if necessary, laminates a c-BP single crystal layer on the recystallized Si single crystal layer by epitaxial growth.

The Si single crystal substrate, depending on the chemical compound semiconductor growing in a vapor phase, may be of a face (100) or (111). Further, the thickness of the Si single crystal substrate is preferably from not less than 100 μm to not more than 1000 μm (Hereafter, it only expresses A to B.) and more preferably 300 μm to 800 μm.

When the thickness of the Si single crystal substrate is less than 100 μm, the mechanical strength becomes insufficient. On the other hand, when it exceeds 1000 μm, the economical loss of the time, energy, and materials for forming is increased.

The thickness of the porous Si single crystal layer or the porous 3C—SiC single crystal layer is preferably 100 nm to 1000 μm, preferably 300 nm to 100 μm and more preferably 1 μm to 50 μm.

When the thickness of the porous Si single crystal layer is less than 300 nm, the function thereof as a buffer layer for stress due to lattice mismatching becomes insufficient and the growth of a single crystal layer formed on it becomes difficult. On the other hand, when it exceeds 1000 μm, the economical loss of the time, energy, and materials for forming is increased.

The thickness of the 3C—SiC single crystal layer covering the surface (or depth) of skeletal part of the porous Si single crystal layer is preferably 0.1 nm to 100 nm, and preferably 5 nm to 50 nm

When the thickness of the 3C—SiC single crystal layer covering the surface of the porous Si single crystal layer is less than 0.1 nm, the function thereof as a buffer layer for stress due to lattice mismatching becomes insufficient. On the other hand, it is difficult to exceed 100 nm due to the physical dimensions of the porous Si single crystal layer.

The thickness of the Si single crystal layer formed on the porous Si single crystal layer or the porous 3C—SiC single crystal layer is 0.1 μm to 5 μm.

When the thickness of the Si single crystal layer is too thin such as less than 0.1 μm, the irregularities of the porous Si single crystal layer are reflected straight and the flatness of the surface becomes insufficient. On the other hand, when it exceeds 5 μm, the further improvement of the quality cannot be desired and waste of the raw material inversely results.

Therefore, the thickness of the Si single crystal layer is preferably 0.1 μm to 5 μm and more preferably 0.2 μm to 2 μm.

The thickness of the 3C—SiC single crystal layer which is formed by carbonization of the Si single crystal layer is preferably 1 nm to 100 nm and more preferably 5 nm to 50 nm.

When the thickness of the 3C—SiC single crystal layer is less than 1 nm, the function thereof as a buffer layer for stress due to lattice mismatching becomes insufficient. On the other hand, when it exceeds 100 nm, the economical loss of the time, energy, and materials for forming is increased.

As for a recrystallization of the porous Si single crystal layer, it is desirable to be carried out in the range of the surface 0.1 nm to 1 μm.

When the thickness of the recrystallized Si single crystal layer by recrystallization is less than 0.1 nm, the chemical compound semiconductor single crystal film becomes porous and the quality is reduced. On the other hand, when it exceeds 1 μm, economical material loss results.

Therefore, the thickness of the recrystallized Si single crystal layer by recrystallization is preferably 1 to 500 nm. Further, the thickness of the recrystallized Si single crystal layer by recrystallization is ⅕ of the thickness of the porous Si layer or less, preferably 1/10 or less.

The thickness of the c-BP single crystal layer is preferably 0.01 μm to 1 μm and more preferably 0.1 μm to 0.5 μm. When the thickness of the c-BP single crystal layer is less than 0.01 μm, defects such as a twinning crystal occur due to the difference in the lattice constant between the recrystallized Si single crystal layer and the chemical compound semiconductor single crystal film and the quality of the chemical compound semiconductor single crystal film is reduced. On the other hand, when it exceeds 1 μm, the quality improvement becomes constant and economical material loss results.

Pores (or pit) of porous Si single crystal layer on Si single crystal substrate open outward. Therefore, carbonization of the porous Si single crystal layer is easy and antiphase domain in a SiC single crystal layer formed on the porous Si single crystal layer is reduced.

As a method for making the upper part of a Si single crystal substrate porous, for example, an anode chemical conversion (anodization) method for performing an anode chemical conversion process by a DC bias in a solution containing HF (hydrofluoric acid) and ethanol and a chemical etching method for dipping the Si single crystal substrate in HNO3 (nitric acid) or HF may be cited.

When the heat treating temperature for carbonizing the porous Si single crystal layer is lower than 800° C., no reaction is produced, causing insufficient carbonization. On the other hand, when the heat treating temperature exceeds 1400° C., it is higher than the melting point of Si, thus the carbonization becomes physically difficult.

Therefore, the heat treating temperature for carbonizing the porous Si single crystal layer is preferably 1000° C. to 1200° C.

The raw material of carbon may include carbon like paraffinic hydrocarbon such as C3H8 (propane), CH4 (methane), and C4H10 (butane) and the state of gas or liquid is no particular object. Further, the raw material of carbon may be diluted with hydrogen.

The vapor phase growth temperature of the non-porous Si single crystal layer is preferably 800° C. to 1200° C. and more preferably 900° C. to 1100° C.

When the vapor phase growth temperature of the Si single crystal layer is lower than 800° C., the raw material is not decomposed and the layer does not grow. On the other hand, when it exceeds 1200° C., pollution by impurities proceeds remarkably.

As a stock gas for vapor phase growth of the Si single crystal layer, for example, in addition to a hydrogenerated silicon stock such as SiH4 (monosilane), silane chloride stocks such as SiH2Cl2 (dichlorosilane) and SiHCl3 (trichlorosilane) are used.

The epitaxial growth temperature of the c-BP single crystal layer is preferably 800° C. to 1100° C. and more preferably 850° C. to 950° C.

When the epitaxial growth temperature of the c-BP single crystal layer is lower than 800° C., the layer becomes polycrystalline and the quality thereof is reduced. On the other hand, when it exceeds 1100° C., the layer is subject to gas decomposition, thereby cannot grow.

As a raw material for epitaxial growth of the c-BP single crystal layer, for example, PH3 (phosphine) and B2H6 (diborane) are used.

For scission or separation of the porous Si single crystal layer the surface layer part of which is carbonized, a thermal shock, a laser cutter, an ultrasonic cutter, and wet etching are used.

As a chemical compound semiconductor grown in a vapor phase on a substrate for growth of chemical compound semiconductor, in addition to 3C—SiC and c-BP, nitrides such as AIN (aluminum nitride), InN (indium nitride), and cubic or hexagonal GaN (gallium nitride) may be cited.

These chemical compounds may be formed instead of the 3C—SiC single crystal layer and may be formed on the 3C—SiC single crystal layer.

### EMBODIMENT 1

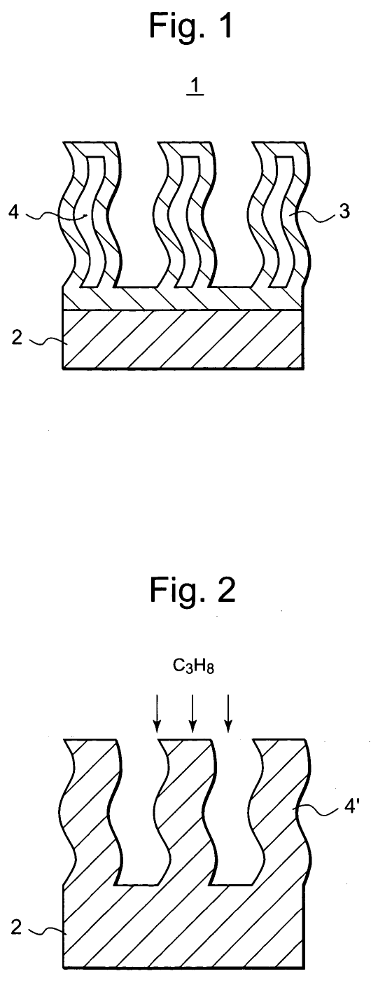

FIG. 1 is a conceptual cross sectional view of a substrate for growth of a chemical compound semiconductor relating to an embodiment of the present invention.

A substrate 1 for growth of a chemical compound semiconductor has porous Si single crystals 4 formed on the top of a Si single crystal substrate 2 with a thickness of 300 μm. The porous Si single crystals 4 are opened outward (upward in FIG. 1). The surface of each of the porous Si single crystals 4 is covered with a 3C—SiC single crystal layer 3 with a thickness of 1 nm. The thickness of the porous Si single crystals 4 is, for example, 10 μm.

To produce the aforementioned substrate 1 for growth of a chemical compound semiconductor, for example, in a solution containing HF and ethanol, a Si single crystal substrate with a thickness of 300 μm and a platinum grid electrode (both are not shown in the drawing) are dipped opposite to each other. Using an aluminum electrode installed on the Si single crystal substrate as an anode and the platinum grid electrode as a cathode, power is supplied from a DC power source to perform the anode chemical conversion process. Then, on the top of the Si single crystal substrate 2 which is a contact face with HF, porous Si single crystal layers 4′ can be formed, for example, in a depth of 10 μm (refer to FIG. 2).

Next, the porous Si single crystal layers 4′ are heat-treated at 1000° C. in a C₃H₈ gas atmosphere (refer to FIG. 2). The surface layer part of each of the porous Si single crystal layers 4′ is carbonized, for example, in a depth of about 1 nm from the surface thereof and the 3C—SiC single crystal layers 3 (refer to FIG. 1) are formed.

The thickness of the 3C—SiC single crystal layers 3 can be adjusted by the porosity of the porous Si single crystal layers 4′ and the time and temperature of the heat treatment in a carbon stock atmosphere.

The substrate 1 for growth of a chemical compound semiconductor is used, and a 3C—SiC single crystal film, which is a chemical compound semiconductor, is laminated with a thickness of 5 μm by vapor phase growth, and crystal defects are checked. Further, as a stock gas, SiH4 (monosilane) and C3H8 are used and the growth temperature is 1150° C.

For comparison, as a substrate for growth of a chemical compound semiconductor, the porous Si single crystal layers of the embodiment 1 are oxidized, and the 3C—SiC single crystal films are laminated similarly, and crystal defects are checked.

The defects of the chemical compound semiconductor of the embodiment 1, as compared with the conventional, are reduced to about 1/10. Further, the conventional substrate for growth of a chemical compound semiconductor is produced by oxidizing the porous Si single crystal layers of the embodiment 1 instead of carbonization. The aim of the oxidization is to prevent the reconstruction of porous Si single crystal layers, because porous Si single crystal layers are sensitive to heat treatment and reconstructs without oxidization or without carbonization.

When laminating a single crystal film of a chemical compound semiconductor, the 3C—SiC single crystal layers function as a buffer layer, so that the occurrence of defects of the chemical compound semiconductor due to lattice mismatching can be reduced. Further, the porous Si single crystal layers can reduce the occurrence of defects of the chemical compound semiconductor due to stress caused by the difference in the thermal expansion coefficient and the chemical compound semiconductor can be made good in quality.

### EMBODIMENT 2

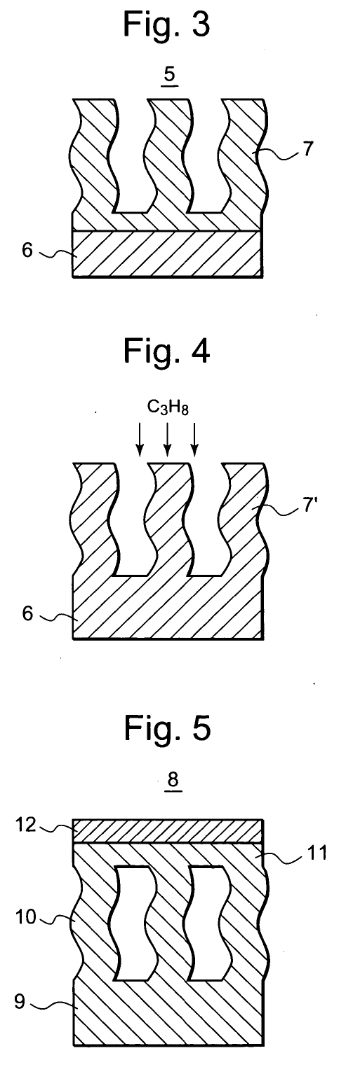

FIG. 3 is a conceptual cross sectional view of a substrate for growth of a chemical compound semiconductor relating to another embodiment of the present invention.

A substrate 5 for growth of a chemical compound semiconductor has porous 3C—SiC single crystal layers 7 formed on a Si single crystal substrate 6 with a thickness of 300 μm. The porous 3C—SiC single crystal layers 7 are opened outward (upward in FIG. 3) and the thickness thereof is, for example, 10 μm.

To produce the substrate 5 for growth of a chemical compound semiconductor, for example, the upper part of the Si single crystal substrate 6 with a thickness of 300 μm is made porous and porous Si single crystal layers 7′ with a thickness of 10 μm which are opened outward are formed (refer to FIG. 4).

Next, the porous Si single crystal layers 7′ are heat-treated (refer to FIG. 4), are carbonized overall, and are transformed to the porous 3C—SiC single crystal layers 7 (refer to FIG. 3).

The heat-treating conditions are, for example, a C₃H₈ gas atmosphere and a temperature of 1000° C.

Further, the thickness of the 3C—SiC single crystal layers 7 can be adjusted by the porosity of the porous Si single crystal layers 7′ and the heat treatment time and heat treatment temperature in a carbon stock atmosphere.

The substrate 5 for growth of a chemical compound semiconductor is used, and a 3C—SiC single crystal film is laminated with a thickness of 5 μm by vapor phase growth, and crystal defects are checked. Further, as a stock gas, SiH₄ (monosilane) and C₃H₈ are used and the growth temperature is 1150° C.

For comparison, as a substrate for growth of a chemical compound semiconductor, the porous Si single crystal layers 7′ of the embodiment 2 are oxidized instead of carbonization, and the 3C—SiC single crystal films are laminated similarly, and crystal defects are checked (a comparison example).

The defects of the chemical compound semiconductor of the embodiment 2, as compared with the comparison example, are reduced to about 1/10.

When laminating a single crystal film of a chemical compound semiconductor, the 3C—SiC single crystal layers function as a buffer layer, so that the occurrence of defects of the chemical compound semiconductor due to lattice mismatching can be reduced. Further, the porous Si single crystal layers can reduce the occurrence of defects of the chemical compound semiconductor due to stress caused by the difference in the thermal expansion coefficient and the chemical compound semiconductor can be made good in quality.

### EMBODIMENT 3

FIG. 5 is a conceptual cross sectional view of a substrate for growth of a chemical compound semiconductor relating to still another embodiment of the present invention.

A substrate 8 for growth of a chemical compound semiconductor is composed of porous Si single crystal layers 10, non-porous Si single crystal layers 11, and 3C—SiC single crystal layers 12 which are sequentially formed on a Si single crystal substrate 9 with a thickness of 300 μm. The porous Si single crystal layers 10 are opened outward (upward in FIG. 5) and the thickness thereof is 10 μm. The Si single crystal layers 11 are non-porous and the thickness thereof is, for example, 1 μm. The thickness of the 3C—SiC single crystal layers 12 is, for example, 1 nm.

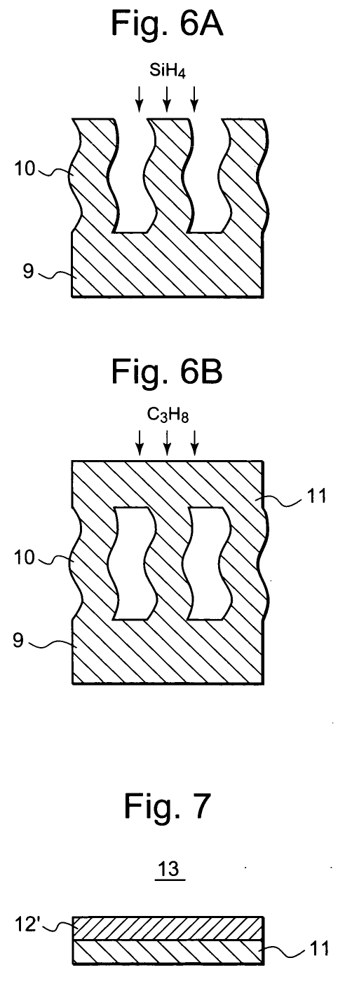

To produce the substrate 8 for growth of a chemical compound semiconductor, for example, the upper part of the Si single crystal substrate 9 with a thickness of 300 μm is made porous in the same way as with the embodiment 1 and the porous Si single crystal layers 10 with a thickness of 10 μm which are opened outward are formed (refer to FIG. 6A).

Next, on the porous Si single crystal layers 10, the non-porous Si single crystal layers 11 with a thickness of 1 μm are laminated (refer to FIG. 6B). The vapor phase growth conditions are, for example, a SiH₄ gas atmosphere and a temperature of 1000° C.

Next, the porous Si single crystal layers 11 are heat-treated (refer to FIG. 6B), and the upper parts of the Si single crystal layers are carbonized in a depth of 1 nm from the surface thereof, and the Si single crystal layers 11 are transformed to the porous 3C—SiC single crystal layers 12 (refer to FIG. 5). The heat-treating conditions are, for example, a C₃H₈ gas atmosphere and a temperature of 1000° C.

The substrate 8 for growth of a chemical compound semiconductor is used, and a 3C—SiC single crystal film is laminated with a thickness of 5 μm by vapor phase growth, and crystal defects are checked. Further, as a stock gas, SiH₄ and C₃H₈ are used and the growth temperature is 1150° C.

For comparison, in the same way as with the aforementioned comparison example, as a substrate for growth of a chemical compound semiconductor, on the upper part of the porous Si single crystal layers 11, the 3C—SiC single crystal films are laminated without carbonization, and crystal defects thereof are checked.

The defects of the chemical compound semiconductor of the embodiment 3, as compared with the comparison example, are reduced to about 1/100.

The non-porous Si single crystal layers fill up the level different portions produced by the porous Si single crystal layers, so that the surface becomes flat on the atomic level. When laminating the single crystal film of chemical compound semiconductor, the occurrence of defects of the chemical compound semiconductor due to the level difference can be reduced and the chemical compound semiconductor can be made better in quality.

### EMBODIMENT 4

FIG. 7 is a conceptual cross sectional view of a substrate for growth of a chemical compound semiconductor relating to a further embodiment of the present invention.

A substrate 13 for growth of a chemical compound semiconductor, although the ones of the embodiments 1 to 3 respectively are equipped with the Si single crystal substrates 2, 6, and 9, is an independent substrate. From the substrate 8 for growth of a chemical compound semiconductor of the embodiment 3, the Si single crystal substrate 9 is removed by scission and separation of the porous Si single crystal layer 10 and on the Si single crystal layer 11 with a thickness of 1 μm, a 3C—SiC single crystal layer 12′ with a thickness of 100 μm is formed.

To produce the substrate 13 for growth of a chemical compound semiconductor, for example, the substrate 8 for growth of a chemical compound semiconductor of the embodiment 3 is used and the 3C—SiC single crystal layer 12′ with a thickness of 100 μm is laminated by vapor phase growth. The treatment conditions are use of SiH₄ and C₃H₈ as a stock gas at 1150° C.

Next, to the Si single crystal layer 11 and the Si single crystal substrate 9, at 400° C. in the temperature fall course after vapor phase growth of the 3C—SiC single crystal layer 12′, a thermal shock is given and the Si single crystal substrate 9 is removed by scission and separation at the porous Si single crystal layer 10. The residual porous Si single crystal layer 10 is removed by HF.

The substrate 13 for growth of a chemical compound semiconductor is used, and a 3C—SiC single crystal film is laminated with a thickness of 5 μm by vapor phase growth, and crystal defects are checked. Further, as a stock gas, SiH₄ and C₃H₈ are used and the growth temperature is 1150° C.

For comparison, the substrate 8 for growth of a chemical compound semiconductor of the embodiment 3 is used, and the 3C—SiC single crystal film is laminated similarly, and crystal defects are checked.

The defects of the chemical compound semiconductor of the embodiment 4, as compared with the comparison example, are reduced to about 1/1000.

When laminating the single crystal film of a chemical compound semiconductor, it is not affected at all by the Si single crystal substrate, so that the occurrence of defects of the chemical compound semiconductor due to lattice mismatching and to stress caused by the difference in the thermal expansion coefficient can be eliminated and the quality can be improved extremely.

### EMBODIMENT 5

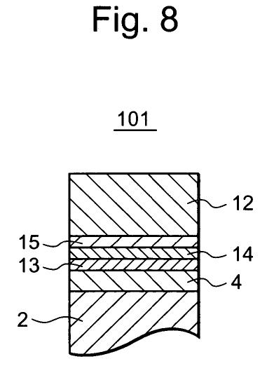

FIG. 8 is a conceptual cross sectional view of a substrate for growth of a chemical compound semiconductor relating to a still further embodiment of the present invention.

In a chemical compound semiconductor 101, on the Si single crystal substrate 2, the porous Si layer 4, the recrystallized Si single crystal layer 13, a c-BP single crystal layer 14, and a 3C—SiC low-temperature grown (amorphous) layer 15 are sequentially laminated to form the 3C—SiC single crystal film 12. The 3C—SiC single crystal film 12 is an active layer.

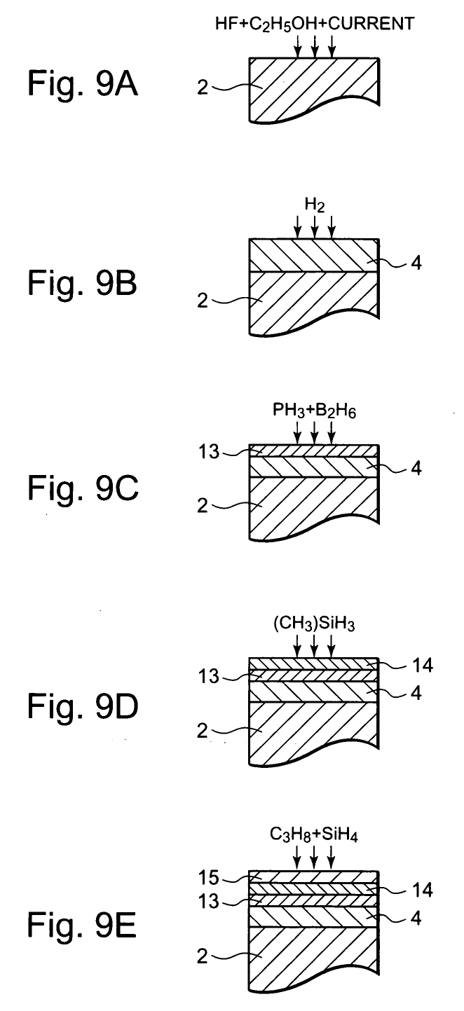

To produce the chemical compound semiconductor 101, for example, in a C₂H₅OH (ethanol) solution containing HF, the Si single crystal substrate 2 and a platinum grid electrode (not shown in the drawing) are dipped opposite to each other. Using an aluminum electrode (not shown in the drawing) installed on the Si single crystal substrate 2 as an anode and the platinum grid electrode as a cathode, power is supplied from a DC power source to perform the anode chemical conversion process (refer to FIG. 9A). Then, on the surface (the top shown in FIG. 8) of the Si single crystal substrate 2 which is a contact face with HF, the porous Si single crystal layer 4 can be formed, for example, in a depth of 10 μm (refer to FIG. 9B).

The porous Si layer 4, by properly changing the anode chemical conversion conditions, for example, the current density, electrolyte, processing time, and impurity concentration in the Si single crystal substrate 2, can control the porosity and depth.

Next, the Si single crystal substrate 2 forming the porous Si layer 4 is annealed in a H₂ atmosphere at 1200° C. for 10 minutes (refer to FIG. 9B). Only Si atoms of the surface layer of the porous Si layer 4 are re-arranged, and the layer is recrystallized in a depth of several nm from the surface thereof, and the recrystallized Si single crystal layer 13 is formed (refer to FIG. 9C).

Next, in the continuation state of feed of H₂, the temperature of the Si single crystal substrate 2 is lowered to 900° C., and then the feed of H₂ is stopped, and B₂H₆ and PH₃ are fed (refer to FIG. 9C), and on the recrystallized Si single crystal layer 13, the c-BP single crystal layer 14 is laminated by epitaxial growth (refer to FIG. 9D).

Next, the feed of B₂H₆ and PH₃ is stopped, and the feed of H₂ is continued, and the temperature of the Si single crystal substrate 2 is lowered, for example, to 800° C., and then CH₃SiH₃ is fed in place of H2 (refer to FIG. 9D), and on the c-BP single crystal layer 14, the 3C—SiC low-temperature grown layer 15 is laminated by low temperature growth (refer to FIG. 9E). The thickness of the 3C—SiC low-temperature grown layer 15 may be within the range from several nm to 1 μm.

Finally, the feed of CH₃SiH₃ is stopped, and the feed of H₂ is continued, and the temperature of the Si single crystal substrate 2 is raised to 1150° C., and then C₃H₈ and SiH₄ are fed in place of H₂, and the temperature of the Si single crystal substrate 2 is kept at 1150° C., and on the 3C—SiC low-temperature grown layer 15, the 3C—SiC single crystal film 12 is laminated by epitaxial growth (refer to FIG. 8).

On the other hand, for comparison, directly on the surface of the Si single crystal substrate, similarly to the aforementioned case, a 3C—SiC single crystal film with the same thickness is laminated.

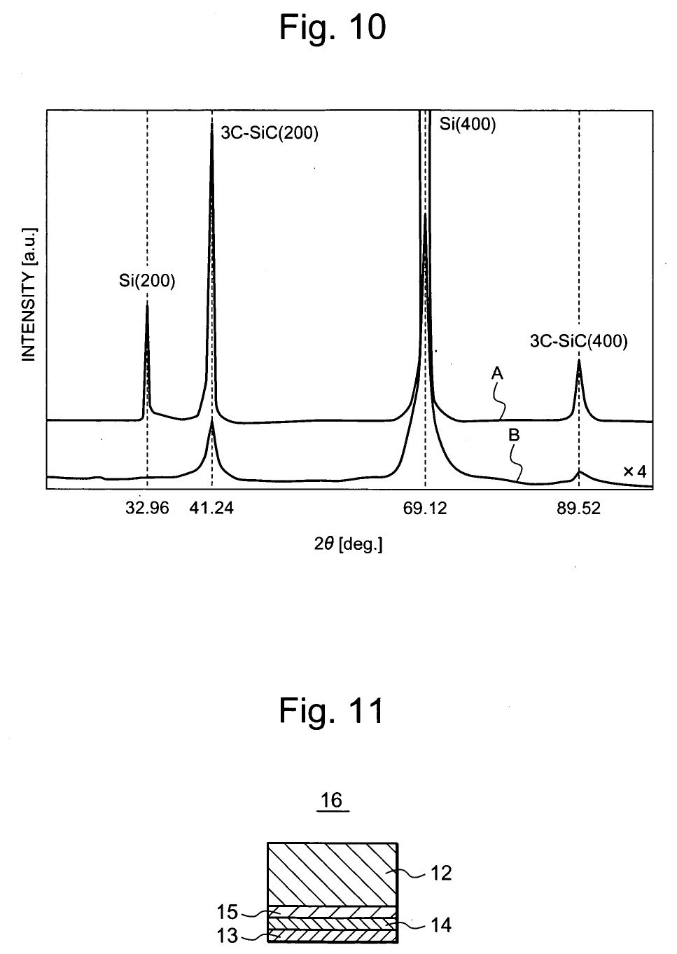

The crystallizability of the 3C—SiC single crystal film 2 of the embodiment 5 and the 3C—SiC single crystal film directly laminated on the Si single crystal substrate for comparison is evaluated by an X-ray diffractor. Assuming the intensity of the 3C—SiC single crystal film 2 of the embodiment 5 as A and the intensity of the one for comparison as B, XRD rocking curves as shown in FIG. 10 are obtained. The axis of abscissa indicates a diffraction angle of 2θ and the axis of ordinate indicates intensity. As shown in FIG. 10, the porous Si layer between the Si single crystal substrate and the 3C—SiC single crystal film functions as a suppression relaxation layer of stress due to the difference in the thermal expansion coefficient, and the c-BP single crystal layer functions as a suppression relaxation layer of stress due to lattice mismatching, and the crystallizability of the3C—SiC single crystal film is improved greatly.

### EMBODIMENT 6

FIG. 11 is a conceptual cross sectional view of a chemical compound semiconductor relating to an embodiment of the present invention.

A chemical compound semiconductor 16, although the one of the embodiment 5 is equipped with the Si single crystal substrate 2, is an independent substrate. On the recrystallized Si single crystal layer 13 with a thickness of about 10 nm, the c-BP single crystal layer 14 with a thickness of about 500 nm and the 3C—SiC low-temperature grown layer 15 with a thickness of about 10 nm are formed and on them, the 3C—SiC single crystal film 12 with a thickness of about 100 μm is formed.

To produce the chemical compound semiconductor 16, for example, the 3C—SiC single crystal layer 12 and the Si single crystal substrate 2 are given a thermal shock at 400° C. in the temperature fall course after lamination of the 3C—SiC single crystal layer 12 of the embodiment 5 and are removed by scission and separation at the porous Si single crystal layer 4. The residual porous Si single crystal layer 4 is removed by HF.

Further, for the Si single crystal substrate used for epitaxial growth of the chemical compound semiconductor film, a porous Si layer which is annealed beforehand in a H₂ atmosphere and in which Si atoms on the uppermost surface of the substrate are re-arranged and recrystallized may be used. In the general vapor phase growth, there is a step of natural oxide layer removal and an annealing step at a temperature slightly higher than the temperature at the removal step may be added. By doing this, it is possible to promote re-arrangement of Si atoms of the uppermost surface of the substrate and recrystallize the uppermost surface at the same time with the natural oxide layer removal.

It goes without saying that various obvious modifications and simple variants come within the scope of the present invention beyond the above-described embodiments.

For example, in the substrate for growth of a chemical compound semiconductor, according to circumstances, the substrate itself can be used as a chemical compound semiconductor and the chemical compound semiconductor may be as a substrate for growth of chemical compound semiconductor.

1. A substrate for growth of chemical compound semiconductor, comprising:
(1) a Si single crystal substrate and
(2) a porous Si single crystal layer which pores opened outward, which is formed on at least one surface of said Si single crystal substrate.

2. A substrate as set forth in claim 1, wherein a thickness of said porous Si single crystal layer is from not less than 100 nm to not more than 1000 μm.

3. A substrate for growth of chemical compound semiconductor, comprising:
(1) a Si single crystal substrate and
(2) a porous Si single crystal layer formed on at least one surface of said Si single crystal substrate, wherein said surface is covered with a 3C—SiC single crystal layer.

4. A substrate as set forth in claim 3, wherein a thickness of said 3C—SiC single crystal layer is from not less than 0.1 nm to not more than 100 nm.

5. A substrate for growth of chemical compound semiconductor, comprising:
(1) a Si single crystal substrate and
(2) a porous Si single crystal layer formed by making an upper part of said Si single crystal substrate porous, wherein a surface layer part thereof is carbonized to a desired depth.

6. A substrate as set forth in claim 5, wherein said porous Si single crystal layer is heat-treated at from not less than 800° C. to not more than 1400° C. in an atmosphere which includes carbon and said surface layer part is carbonized in a depth of from not less than 0.1 nm to not more than 100 nm from said surface.

7. A substrate for growth of chemical compound semiconductor, comprising:
(1) a Si single crystal substrate,
(2) a porous Si single crystal layer formed on at least one surface of said Si single crystal substrate, and
(3) a SiC single crystal layer formed on said porous Si single crystal layer.

8. A substrate for growth of chemical compound semiconductor, comprising:
(1) a Si single crystal substrate,
(2) a porous Si single crystal layer formed on said Si single crystal substrate, wherein a surface layer part thereof is carbonized to a desired depth, and
(3) a SiC single crystal layer formed on said porous Si single crystal layer.

9. A substrate for growth of chemical compound semiconductor, comprising:
(1) a Si single crystal substrate,
(2) a porous Si single crystal layer formed on said Si single crystal substrate, wherein a surface layer thereof is recrystallized, and
(3) a SiC single crystal layer formed on said porous Si single crystal layer.

10. A substrate for growth of chemical compound semiconductor, comprising:
(1) a Si single crystal substrate and
(2) a porous 3C—SiC single crystal layer which pores opened outward, which is formed on at least one surface of said Si single crystal substrate.

11. A substrate for growth of chemical compound semiconductor, comprising:
(1) a Si single crystal substrate
(2) a porous Si single crystal layer which pores opened outward which is formed on at least one surface of said Si single crystal substrate
(3) a Si single crystal layer with a thickness of 0.1 to 5 μm which is formed on said porous Si single crystal layer, and
(4) a 3C—SiC single crystal layer which is formed on said Si single crystal layer.

12. A chemical compound semiconductor, comprising:
(1) a Si single crystal substrate,
(2) a porous Si single crystal layer formed on said Si single crystal substrate, wherein a surface layer thereof is recrystallized,
(3) a c-BP single crystal layer formed on said porous Si single crystal layer, and
(4) a chemical compound semiconductor single crystal film formed on said c-BP single crystal layer.

13. A chemical compound semiconductor, comprising:
(1) a Si single crystal substrate,
(2) a porous Si single crystal layer formed on said Si single crystal substrate,
(3) a SiC single crystal layer formed on said porous Si single crystal layer, and
(4) a 3C—SiC single crystal layer formed on said SiC single crystal layer.

14. A substrate as set forth in claim 13, wherein a thickness of said SiC single crystal layer is from not less than 0.1 μm to not more than 5 μm.

15. A substrate as set forth in claim 13, wherein said Si single crystal substrate is removed by scission or separation of said porous Si single crystal layer.

16. A process for producing a substrate for growth of chemical compound semiconductor, comprising the steps of:
(1) forming a porous Si single crystal layer by making at least one surface of a Si single crystal substrate porous and
(2) heat-treating said porous Si single crystal layer at from not less than 800° C. to not more than 1400° C. in an atmosphere which includes carbon and carbonizing a whole thereof.

17. A process for producing a substrate for growth of chemical compound semiconductor, comprising the steps of:
(1) forming a porous Si single crystal layer by making at least one surface of a Si single crystal substrate porous,
(2) laminating a Si single crystal film with a thickness of from not less than 0.1 μm to not more than 5 μm on said porous Si single crystal film by vapor deposition, and
(3) heat-treating said Si single crystal film at from not less than 800° C. to not more than 1400° C. in an atmosphere which includes carbon and carbonizing a surface thereof.

18. A process as set forth in claim 17, wherein:
after carbonization of an upper part of said Si single crystal layer, said Si single crystal substrate is removed by scission or separation of said porous Si single crystal layer.

19. A process for producing a substrate for growth of chemical compound semiconductor, comprising the steps of:
(1) forming a porous Si layer in a depth of from not less than 300 nm to not more than 50 μm from at least one surface of a Si single crystal substrate and
(2) annealing said porous Si layer at from not less than 800° C. to not more than 1200° C. in a H₂ atmosphere and recrystallizing a surface layer thereof in a depth of from not less than 0.1 nm to not more than 1 μm.

20. A process for producing a substrate for growth of chemical compound semiconductor, comprising the steps of:
(1) forming a porous Si layer in a depth of from not less than 300 nm to not more than 50 μm from surface of a Si single crystal substrate,
(2) annealing said porous Si layer at from not less than 800° C. to not more than 1200° C. in a H₂ atmosphere and recrystallizing a surface layer thereof in a depth of from not less than 0.1 nm to not more than 1 μm,
(3) laminating a c-BP single crystal layer on said recrystallized Si single crystal layer by epitaxial growth, and
(4) laminating a chemical compound semiconductor single crystal film on said c-BP single crystal layer by epitaxial growth.

21. A process as set forth in claim 20, wherein:
after lamination of said chemical compound semiconductor single crystal film, said chemical compound semiconductor single crystal film and said Si single crystal substrate are cut and separated on said porous Si layer.
